(19) United States
(12) Patent Application Publication
(10) Pub. No.: US 2019/0181030 A1
(43) Pub. Date: Jun. 13, 2019

(54) Separation Device and Separation Method for Film and Wafer

(71) Applicant: Beijing Chuangyu Technology Co., Ltd, Beijing (CN)

(72) Inventors: Jincheng ZOU, Beijing (CN); Min WEI, Beijing (CN)

(21) Appl. No.: 16/019,583

(22) Filed: Jun. 27, 2018

(30) Foreign Application Priority Data
Dec. 13, 2017 (CN) 201711326700.X

(51) Int. Cl. H01L 21/683; H01L 21/687; H01L 21/67; H01L 31/18

(52) U.S. Cl. CPC H01L 21/6838; H01L 21/68721; H01L 31/18; H01L 21/67092; H01L 21/68792; H01L 21/68728

(57) ABSTRACT

The present disclosure relates to a technical field of solar cells, and more particularly to a separation device and a separation method for a film and a wafer. The separation device includes a base, a first suction plate, a driving mechanism, a swinging rod, and a clamping mechanism, wherein the first suction plate is horizontally provided on the base, and the first suction plate is fitted and sucked to a lower surface of a wafer; one end of the swinging rod is connected with the driving mechanism, and the other end of the swinging rod is connected with the clamping mechanism; the driving mechanism is used for driving the swinging rod and the clamping mechanism to swing in a vertical plane so that the swinging rod and the clamping mechanism get close to or away from the first suction plate.

### TECHNICAL FIELD

The present disclosure relates to a technical field of solar cells, and more particularly to a separation device and a separation method for a film and a wafer.

### BACKGROUND

New energy is one of the five most decisive technical fields in the world economic development in the twenty-first century. Solar energy is a new energy that is clean, efficient and inexhaustible. In the new century, national governments emphasize utilization of solar energy resources in the national sustainable development strategy. Photovoltaic power generation has the advantages of safety, reliability, noiselessness, no pollution, few restrictions, low failure rate, simple maintenance and the like.

A wafer and a film of a solar cell are fitted together by means of a surface tension, when it is necessary to separate the wafer and the film, a related separation device often needs to spray water to a junction surface of the wafer and the film to separate the wafer and the film, but the water may be splashed to a film suction mechanism in this process, so as to destroy the vacuum of the film suction mechanism, thereby resulting in separation failure.

### SUMMARY

### (1) Technical Problem to Be Solved

The technical problem to be solved by some embodiments of the present disclosure is a problem that a suction mechanism may be destroyed by water sprayed when a related separation device separates a wafer and a film.

### (2) Technical Solution

In order to solve the above technical problem, some embodiments of the present disclosure provide a separation device for a film and a wafer. The device includes a base, a first suction plate, a driving mechanism, a swinging rod, and a clamping mechanism. The first suction plate is horizontally provided on the base, a film and a wafer, to be separated, are placed on the first suction plate, and the first suction plate is fitted and sucked to a lower surface of the wafer. One end of the swinging rod is connected with the driving mechanism, and the other end of the swinging rod is connected with the clamping mechanism. The driving mechanism is used for driving the swinging rod and the clamping mechanism to swing in a vertical plane so that the swinging rod and the clamping mechanism get close to or away from the first suction plate. The clamping mechanism is used for clamping the film at an edge of the film.

In an exemplary embodiment, the clamping mechanism includes a first cylinder and a second cylinder. The first cylinder is connected with the swinging rod, and a telescopic rod of the first cylinder is provided along a direction away from the swinging rod. The second cylinder is connected with the telescopic rod of the first cylinder, and a telescopic rod of the second cylinder is perpendicular to the telescopic rod of the first cylinder. An end portion of the telescopic rod of the second cylinder is connected with a pressing plate, and the pressing plate is used for pressing against a lower surface of the film.

In an exemplary embodiment, an upper surface of the pressing plate is provided with an elastic strip, the elastic strip is used for implementing an elastic contact between the pressing plate and the lower surface of the film.

In an exemplary embodiment, the driving mechanism is provided on the base, the driving mechanism includes a driving motor and a rotating shaft, the driving motor is provided on the base through a motor fixing seat, an output shaft of the driving motor is horizontally provided, and an output shaft of the driving motor is connected with the rotating shaft through a coupling. The swinging rod is perpendicular to the rotating shaft, and is fixedly connected with the rotating shaft. Two ends of the rotating shaft are provided with a bearing fixing seat separately. The bearing fixing seats are fixed to the base, and a bearing is provided in each bearing fixing seat. The rotating shaft penetrates through the bearings and is matched with an inner ring of the bearings.

In an exemplary embodiment, the separation device for the film and the wafer further includes a first connecting block. The first connecting block is provided on the base, the first connecting block and the first suction plate are provided on the same side of the rotating shaft, a first vacuum generator is provided in the first connecting block, a first vacuum passage is provided in the first suction plate, and the first vacuum generator is communicated with the first vacuum passage.

In an exemplary embodiment, the separation device for the film and the wafer further includes a second suction plate and a second connecting block. The second suction plate is connected with the swinging rod through the second connecting block, the clamping mechanism is provided on the second suction plate, a second vacuum passage is provided in the second suction plate, a second vacuum generator is provided in the second connecting block, the second vacuum generator is communicated with the second vacuum passage, and the second suction plate is used for contacting and sucking the film when being close to the first suction plate.

In an exemplary embodiment, the swinging rod is provided with a buffer plunger, and when the second suction plate is close to the first suction plate to contact and suck the film, a lower end of the buffer plunger is in contact with the first connecting block.

Some embodiments of the present disclosure also provide a separation method for a film and a wafer, which is used for separating a film and a wafer by using the above separation device. The method includes the following steps:

S1. A wafer and a film, to be separated, are placed on a first suction plate, and the wafer is fitted and sucked by the first suction plate.

S2. A driving motor is controlled to rotate to drive a swinging rod to swing to the film, and the film is clamped at an edge of the film by a clamping mechanism.

S3. The driving motor is controlled to reversely rotate to drive the swinging rod to swing along a direction away from the wafer, and the film is separated from the wafer.

In an exemplary embodiment, step S2 further includes:

S21. The driving motor is controlled to rotate to drive the swinging rod and a second suction plate to rotate above the film, and the second suction plate is controlled to suck an upper surface of the film,

S22. A retraction of a telescopic rod of a first cylinder makes a pressing plate located below the second suction plate, and a retraction of a telescopic rod of a second cylinder makes the pressing plate press against a lower surface of the film.

In an exemplary embodiment, before step S1, the method further includes step S0: the driving motor is controlled to rotate to drive the swinging rod to swing so as to make the second suction plate and the first suction plate located on two sides of a rotating shaft respectively, and the telescopic rod of the first cylinder and the telescopic rod of the second cylinder are controlled to stretch to make the pressing plate away from the second suction plate.

### (3) Beneficial Effect

The above technical solution of the present disclosure has the following advantages. Some embodiments of the present disclosure provide a separation device and a method for, a film and a wafer. The separation device includes a base, a first suction plate, a driving mechanism, a swinging rod, and a clamping mechanism. The first suction plate is horizontally provided on the base, and a film and a wafer, to be separated, are placed on the first suction plate, wherein the first suction plate is fitted and sucked to the lower surface of the wafer. One end of the swinging rod is connected with the driving mechanism, and the other end of the swinging rod is connected with the clamping mechanism. The driving mechanism is used for driving the swinging rod and the clamping mechanism to swing in a vertical plane to be close to or away from the first suction plate. The clamping mechanism is used for clamping the film at the edge of the film. During use, the driving mechanism is first controlled to drive the swinging rod and the clamping mechanism to rotate to a side different from the first suction plate, the wafer and the film are placed on the first suction plate, the first suction plate sucks the wafer by vacuum, the driving mechanism drives the swinging rod to swing to enable the swinging rod and the clamping mechanism to rotate above the film, and then controls the clamping mechanism to clamp and fix the film at the edge of the film, and the driving mechanism drives the swinging rod to swing along, a direction away from the wafer. Since the clamping mechanism clamps the film, the wafer is sucked and fixed by the first suction plate, and when the swinging rod swings along a direction away from the wafer, the film and the wafer are separated. The separation device has a simple structure, the film and the wafer cannot be damaged in a separation process, and the separation efficiency is high.

Besides the above-described technical problem to be solved by the present disclosure, the technical features of the technical solution and the advantages brought by these technical features of the technical solution, other technical features of the present disclosure and advantages brought by these technical features will be further illustrated with reference to the accompanying drawings.

### BRIEF DESCRIPTION OF THE DRAWINGS

FIG. 1 is a schematic structure diagram of a separation device for a film and a wafer according to an embodiment of the present disclosure;

FIG. 2 is a side view of a separation device for a film and a wafer according to an embodiment of the present disclosure;

FIG. 3 is a state diagram illustrating a state where a second suction plate and a first suction plate are located on two sides of a rotating shaft in an embodiment of the present disclosure;

FIG. 4 is a state diagram illustrating a state where a second suction plate and a clamping mechanism press a film in an embodiment of the present disclosure; and

FIG. 5 is a partial enlarged view of FIG. 4.

In the drawings, 1, base; 2, driving motor; 3, motor fixing seat; 4, coupling; 5, bearing, fixing seat; 6, rotating shaft; 7, swinging rod; 8, first connecting block; 9- first suction plate; 10, second connecting block; 11, second suction plate; 12, first cylinder; 13 connecting plate; 14, second cylinder; 15, pressing plate; 16, elastic strip; 17, buffer plunger; 21, film; 22, wafer.

### DETAILED DESCRIPTION OF THE EMBODIMENTS

In order to make the objectives, technical solutions and advantages of some embodiments of the present disclosure clearer, the technical solutions in the embodiments of the present disclosure will be clearly and completely described herein below with the drawings in the embodiments of the present disclosure. Obviously, the described embodiments are only part of the embodiments of the present disclosure, not all of the embodiments. On the basis of the embodiments of the present disclosure, all other embodiments obtained on the premise of no creative work of a person of ordinary skill in the art fall within the scope of protection of the present disclosure.

In the descriptions of the present disclosure, unless otherwise specified and limited, it should be noted that terms “mounting”, “mutual connection” and “connection” should be generally understood. For example, the term may be fixed connection, or detachable connection or integrated connection, may be mechanical connection or electrical connection, may be direct connection, may be indirect connection through an intermediate, or may be internal communication between two elements. A person of ordinary skill in the art may understand specific meanings of the above terms in the present disclosure according to an exemplary embodiment.

In addition, in some embodiments of the present disclosure, unless otherwise specified and limited, “multiple”, “multiple pieces” and “multiple groups” mean two or more, and “several”, “several pieces” and “several groups” mean one or more.

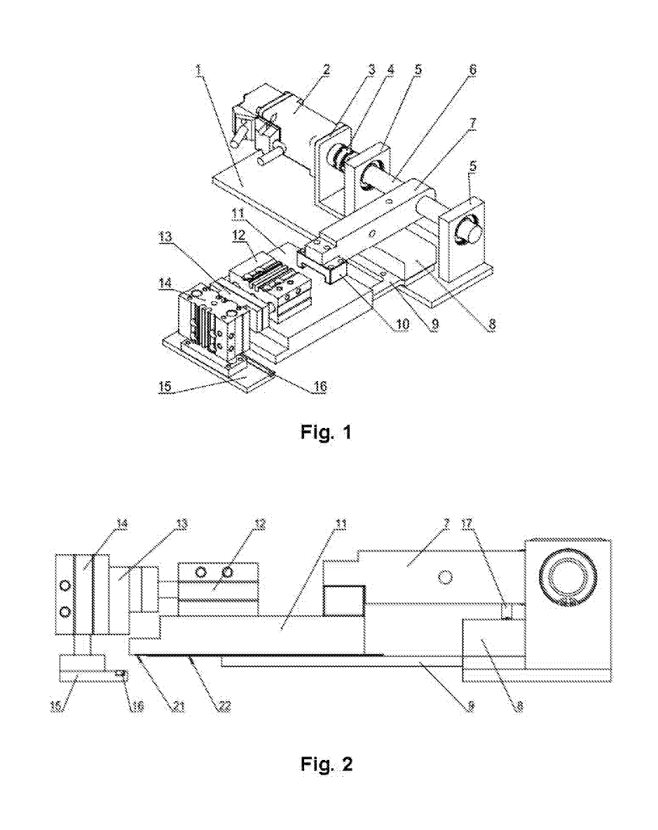

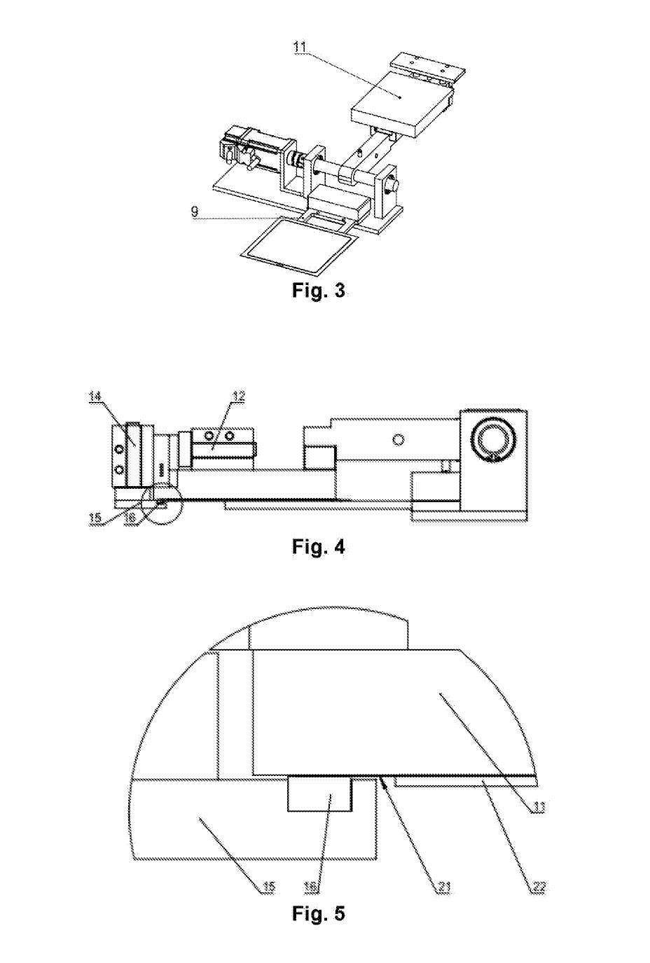

As shown in FIG. 1 to FIG. 5, a separation device for a film and a wafer provided according to an embodiment of the present disclosure includes a base 1, a first suction plate 9, a driving mechanism, a swinging rod 7, and a clamping mechanism. The first suction plate 9 is horizontally provided on the base 1, a film 21 and a wafer 22, to be separated, are placed on the first suction plate 9, the wafer 22 and the film 21 protrude from the first suction plate 9, and the first suction plate 9 is fitted to and sucked a lower surface of the wafer 22. One end of the swinging rod 7 is connected with the driving mechanism, and the other end of the swinging rod 7 is connected with the clamping mechanism. The driving mechanism is used for driving the swinging rod 7 and the clamping mechanism to swing in a vertical plane to be close to or away from the first suction plate 9. The clamping mechanism is used for clamping the film 21 at an edge of the film 21. During use, the driving mechanism is first controlled to drive the swinging rod 7 and the clamping mechanism to rotate to a side different from the first suction plate 9, the wafer 22 and the film 21 are placed on the first suction plate 9, the first suction plate 9 sucks the wafer 22 by vacuum, the driving mechanism drives the swinging rod 7 to swing to enable the swinging rod and the clamping mechanism to rotate above the film 21, and then controls the clamping mechanism to clamp and fix the film 21 at an edge of the film 21, and the driving mechanism drives the swinging rod 7 to swing along a direction away from the wafer 22. Since the clamping mechanism clamps the film 21, the wafer 22 is sucked and fixed by the first suction plate 9, and when the swinging rod 7 swings along a direction away from the wafer 22, the film 21 and the wafer 22 are separated. The separation device has a simple structure, the film 21 and the wafer 22 cannot be damaged during a separation process, and the separation efficiency is high.

In an exemplary embodiment, the clamping mechanism includes a first cylinder 12 and a second cylinder 14. The first cylinder 12 is connected with the swinging rod 7, and a telescopic rod of the first cylinder 12 is provided along a direction away from the swinging rod 7. The second cylinder 14 is connected with the telescopic rod of the first cylinder 12 through a connecting plate 13, and a telescopic rod of the second cylinder 14 is provided along a direction perpendicular to the first cylinder 12. An end portion of the telescopic rod of the second cylinder 14 is connected with a pressing plate 15, and the pressing plate 15 is used for pressing against a lower surface of the film 21.

In an exemplary embodiment, an upper surface of the pressing plate 15 is provided with an elastic strip 16, the elastic strip 16 being used for implementing an elastic contact between the pressing plate 15 and the lower surface of the film 21. In an exemplary embodiment, the elastic strip 16 is made of rubber.

In an exemplary embodiment, the driving mechanism is provided on the base 1. The driving mechanism includes a driving motor 2 and a rotating shaft 6, an output shaft of the driving motor 2 is horizontally provided, and the output shaft of the driving motor 2 is connected with the rotating shaft 6 through a coupling 4. The swinging rod 7 is perpendicular to the rotating shaft 6, and the swinging rod 7 is fixedly connected with the rotating shaft 6. In an exemplary embodiment, one end of the swinging rod 7 is provided with a trepan boring, the trepan boring is sleeved with the rotating shaft 6, and when the rotating shaft 6 rotates, the swinging rod 7 is driven to swing in the vertical plane.

In an exemplary embodiment, two ends of the rotating shaft 6 are provided with a bearing fixing seat 5 separately. The bearing fixing seats 5 are fixed to the base 1, and a bearing is provided in the bearing fixing seat 5. An outer ring of the bearing is fixed in a hole of the bearing fixing seat 5. The rotating shaft 6 penetrates through the bearings and is matched with an inner ring of the bearings. The bearing fixing seats 5 support the rotating shaft 6.

In an exemplary embodiment, the base 1 is also provided with a motor fixing seat 3, the motor fixing seat 3 being used for mounting the driving motor 2. The motor fixing seat 3 is of an L-shape, a bottom plate of the motor fixing seat 3 is fixed to the base 1, and a vertical plate of the motor fixing seat 3 is used for mounting the motor.

In an exemplary embodiment, the separation device also includes a first connecting block 8. The first connecting block 8 is provided on the base 1, the first connecting block 8 and the first suction plate 9 are provided on the same side of the rotating shaft 6, a first vacuum generator is provided in the first connecting block 8, a first vacuum passage is provided in the first suction plate 9, and the first vacuum generator is communicated with the first vacuum passage. The first suction plate 9 generates vacuum by the first vacuum generator, thereby achieving a suction effect of the first suction plate 9 to the wafer 22.

In an exemplary embodiment, the separation device also includes a second suction plate 11 and a second connecting block 10. The second connecting block 10 is provided between the swinging rod 7 and the second suction plate 11. The clamping mechanism is provided on the second suction plate 11. The second suction plate 11 contacts and sucks the film 21 when being close to the first suction plate 9. A second vacuum generator is provided in the second connecting block 10. A second vacuum passage is provided in the second suction plate 11. The second vacuum generator is communicated with the second vacuum passage. In some embodiments, one side of the second connecting block 10 is connected with an end portion of the swinging rod 7, and the other side of the second connecting block 10 is connected with an end, close to the rotating shaft 6, of the second suction plate 11. Vacuum is generated in the second suction plate 11 by means of the second vacuum generator, thereby achieving a suction effect of the second suction plate 11 to the film 21. In an exemplary embodiment, the first cylinder 12 is provided on the second suction plate 11 and is located at the end, away from the rotating shaft 6, of the second suction plate 11. The telescopic rod of the first cylinder is provided along a direction away from the rotating shaft, and the telescopic rod of the second cylinder 14 is perpendicular to the second suction plate 11. After the first suction plate 9 sucks the film 21, the telescopic rods of the first cylinder 12 and the second cylinder 14 are adjusted, so that the pressing plate presses against the lower surface of the film 21 and exerts an acting force on the film 21 from below. A size of the film 21 is greater than that of the wafer 22, the pressing plate 15 presses against the lower surface of the film 21 at the edge of the film 21, so that the film 21 is fitted to the second suction plate 11 thereby making the film 21 move together with the second suction plate 11.

In an exemplary embodiment, the swinging rod 7 is provided with a buffer plunger 17, and when the second suction plate 11 is close to the first suction plate 9 so as to contact and suck the film 21, a lower end of the buffer plunger 17 contacts the first connecting block 8. In an exemplary embodiment, the form of the buffer plunger 17 is a spring plunger. By arranging the buffer plunger 17, when the swinging rod 7 drives the second suction plate 11 to be close to the first suction plate 9, a buffering function is achieved, and when the second suction plate 11 presses against the film 21, a limiting function is achieved.

When the separation device for the film 21 and the wafer 22 is used, the following steps are mainly included.

S0. The driving mechanism is controlled to drive the swinging rod 7 to swing, that is to say, the driving motor 2 rotates to drive the rotating shaft 6 to rotate, and meanwhile, the swinging, rod 7 swings to make the second suction plate 11 and the first suction plate 9 located on two sides of the rotating shaft 6 respectively. The telescopic rod of the first cylinder 12 and the telescopic rod of the second cylinder 14 are controlled to stretch to make the pressing plate 15 away from the second suction plate 11. At this time, the second suction plate 11 is located at an initial position.

S1. The film 21 and, the wafer 22 are placed on the first suction plate 9, and the first suction plate 9 is controlled to suck a lower surface of the wafer 22. When the film 21 and the wafer 22 are placed on the first suction plate 9, a size of the film 21 is greater than that of the wafer 22, space is reserved for pressing of the, pressing plate 15, and suction of the first suction plate 9 for the wafer 22 is implemented by generating vacuum in the first vacuum passage via the first vacuum generator.

S2. The driving motor 2 is controlled to rotate to drive the swinging rod 7 and the second suction plate 11 to rotate above the film 21, and the film 21 is clamped at an edge of the film 21 by the clamping mechanism.

In an exemplary embodiment, step S2 further includes S21. The driving motor 2 rotates to drive the swinging rod 7 and the second suction plate 11 to rotate above the film 21, and the second suction plate 11 is controlled to suck an upper surface of the film 21. In this process, when the second suction plate 11 will contact the film 21, the driving motor 2 slowly rotates to make the second suction plate 11 slowly contact the film 21, and vacuum suction is performed after the film 21 is pressed, thereby avoiding damage during quick contact between the second suction plate 11 and the film 21.

S22. A retraction of the telescopic rod of the first cylinder 12 makes the pressing plate 15 close to the second suction plate 11 and located below the second suction plate 11, and the retraction of the telescopic rod of the second cylinder 14 makes the pressing plate generate an upward displacement and makes the pressing plate 15 press against a lower surface of the film 21. When the pressing plate 15 is close to and in contact with the lower surface of the film 21, the elastic strip 16 located on the pressing plate 15 first contacts the film 21.

S3. The driving motor 2 rotates along a direction opposite to the direction in step S2 to drive the swinging rod 7, the second suction plate 11, the first cylinder 12, the second cylinder 14 and the pressing plate 15 to swing together along a direction away from the wafer 22, so the film 21 is separated from the wafer 22. After the film 21 and the wafer 22 are separated, the driving motor 2 quickly drives, the second suction plate 11 to return to an initial position. Then, telescopic rods of the first cylinder 12 and the second cylinder 14 are controlled to stretch, a constraining force of the pressing plate 15 to the film 21 is canceled, vacuum in the second suction plate 11 is released, a suction force of the second suction plate 11 on the film 21 disappears, and the film 21 may be taken away by using a manipulator. Vacuum in the first suction plate 9 is released, a suction force of the first suction plate 9 on the wafer 22 disappears, and the wafer 22 may be taken away by using a manipulator.

During use, the above actions are repeated, and wafer and film separation may be performed for many times.

To sum up, according to the separation device and method for a film and a wafer provided in the embodiments of the present disclosure, the wafer is sucked by using the first suction plate horizontally provided, the film is sucked by using the second suction plate that can swing in the vertical plane, and one end of the film is pressed by using the movable pressing plate. Thus, when the driving motor rotates, the swinging rod, the second suction plate and the pressing plate are driven to rotate together to achieve separation of the film and the wafer. In the separation process, it is unnecessary to spray water to the film and the wafer. Moreover, the separation device is provided with protection mechanisms such as the elastic strip and the buffer plunger, thereby avoiding damage to the separation mechanism, the film and the wafer in the separation process, and improving the safety, reliability and success rate of separation.

It shall be, finally, noted that: the above embodiments are merely intended to illustrate the technical solutions of the present disclosure and do not limit the technical solutions; although the present disclosure is illustrated in detail with reference to the above embodiments, a person of ordinary skill in the art shall understand that they can still modify the technical solutions recorded by the above embodiments or can equivalently replace some of the technical features; and these modifications or replacements do not make the essences of corresponding technical solutions depart from the spirit and scope of the technical solutions in each embodiment of the present disclosure.

What is claimed is:

1. A separation device for a film and a wafer, comprising a base, a first suction plate, a driving mechanism, a swinging rod, and a clamping mechanism, wherein
the first suction plate is horizontally provided on the base, a film and a wafer, to be separated, are placed on the first suction plate, and the first suction plate is fitted and sucked to a lower surface of the wafer; one end of the swinging rod is connected with the driving mechanism, and the other end of the swinging rod is connected with the clamping mechanism; the driving mechanism is used for driving the swinging rod and the clamping mechanism to swing in a vertical plane so that the swinging rod and the clamping mechanism get close to or away from the first suction plate; and the clamping mechanism is used for clamping the film at an edge of the film.

2. The separation device for the film and the wafer as claimed in claim 1, wherein the clamping mechanism comprises a first cylinder and a second cylinder; the first cylinder is connected with the swinging rod, and a telescopic rod of the first cylinder is provided along a direction away from the swinging rod; the second cylinder is connected with the telescopic rod of the first cylinder, and a telescopic rod of the second cylinder is perpendicular to the telescopic rod of the first cylinder; and an end portion of the telescopic rod of the second cylinder is connected with a pressing plate, and the pressing plate is used for pressing against a lower surface of the film.

3. The separation device for the film and the wafer as claimed in claim 2, wherein an upper surface of the pressing plate is provided with an elastic strip, the elastic strip is used for implementing an elastic contact between the pressing plate and the lower surface of the film.

4. The separation device for the film and the wafer as claimed in claim 2, wherein the driving mechanism is provided on the base, the driving mechanism comprises a driving motor and a rotating shaft, the driving motor is provided on the base through a motor fixing seat, an output shaft of the driving motor is horizontally provided, and the output shaft of the driving motor is connected with the rotating shaft through a coupling; the swinging rod is perpendicular to the rotating shaft, and is fixedly connected with the rotating shaft; two ends of the rotating shaft are provided with a bearing fixing seat separately; the bearing fixing seats are fixed to the base, and a bearing is provided in each bearing fixing seat; and the rotating shaft penetrates through the bearings and is matched with an inner ring of the bearings.

5. The separation device for the film and the wafer as claimed in claim 4, further comprising a first>connecting block, wherein the first connecting block is provided on the base, the first connecting block and the first suction plate are provided on the same side of the rotating shaft, a first vacuum generator is provided in the first connecting block, a first vacuum passage is provided in the first suction plate, and the first vacuum generator is communicated with the first vacuum passage.

6. The separation device for the film and the wafer as claimed in claim 5, further comprising a second suction plate and a second connecting block, wherein the second suction plate is connected with the swinging rod through the second connecting block, the clamping mechanism is provided on the second suction plate, a second vacuum passage is provided in the second suction plate, a second vacuum generator is provided in the second connecting block, the second vacuum generator is communicated with the second vacuum passage, and the second suction plate is used for contacting and sucking the film when being close to the first suction plate.

7. The separation device for the film and the wafer as claimed in claim 6, wherein the swinging rod is provided with a buffer plunger, and when the second suction plate is close to the<first suction plate to contact and suck the film, a lower end of the buffer plunger is in contact with the first connecting block.

8. A separation method for a film and a wafer, separating a film and a wafer by using the separation device as claimed in claim 6, comprising the following steps:
S1. a wafer and a film, to be separated, are placed on a first suction plate, and the wafer is fitted and sucked by the first suction plate;
S2. a driving motor is controlled to rotate to drive a swinging rod to swing to the film, and the film is clamped at an edge of the film by a clamping mechanism; and
S3. the driving motor is controlled to reversely rotate to drive the swinging rod to swing along a direction away from the wafer, and the film is separated from the wafer.

9. The separation method for the film and the wafer as claimed in claim 8, wherein step S2 further comprises:
S21, the driving motor is controlled to rotate to drive the swinging rod and a second suction plate to rotate above the film, and the second suction plate is controlled to suck an upper surface of the film; and
S22. a retraction of a telescopic rod of a first cylinder makes a pressing plate located below the second suction plate, and a retraction of a telescopic rod of a second cylinder makes the, pressing plate press against a lower surface of the film.

10. The separation method for the film and the wafer as claimed in claim 8, wherein before step S1, the method further comprises step S0: the driving motor is controlled to rotate to drive the swinging rod to swing so as to make the second suction plate and the first suction plate located on two sides of a rotating shaft respectively, and the telescopic rod of the first cylinder and the telescopic rod of the second cylinder are controlled to stretch to make the pressing plate away from the second suction plate.

11. The separation device for the film and the wafer as claimed in claim 3, wherein the driving mechanism is provided on the base, the driving mechanism comprises a driving motor and a rotating shaft, the driving motor is provided on the base through a motor fixing seat, an output shaft of the driving motor is horizontally provided, and the output shaft of the driving motor is connected with the rotating shaft through a coupling; the swinging rod is shaft; two ends of the rotating shaft are provided with a bearing fixing seat separately; the bearing fixing seats are fixed to the base, and a hearing is provided in each bearing fixing seat; and the rotating shaft penetrates through the bearings and is matched with an inner ring of the bearings.

12. A separation method for a film and a wafer, separating a film and a wafer by using the separation device as claimed in claim 7, comprising the following steps:
S1. a wafer and a film, to be separated, are pieced on a first suction plate, and the wafer is fitted and sucked by the first suction plate;
S2, a driving motor is controlled to rotate to drive a swinging rod to swing to the film, and the film is clamped at an edge of the film by a damping mechanism; and
S3, the driving motor is controlled to reversely rotate to drive the swinging rod to swing along a direction away from the wafer and the him is separated from the wafer.

13. The separation method for the film and the wafer as claimed in claim 9, wherein before step S1, the method further comprises step S0: the driving motor is controlled to rotate to drive the swinging rod to swing so as to make the second suction plate and the first suction plate located on two sides of a rotating shaft respectively, and the telescopic rod of the first cylinder and the telescopic rod of the second cylinder are controlled to stretch to make the pressing plate away from the second suction plate.
